(19) United States
(12) Patent Application Publication
(10) Pub. No.: US 2024/0347402 A1
(43) Pub. Date: Oct. 17, 2024

(54) METHODS AND APPARATUS TO REDUCE DELAMINATION IN HYBRID CORES

(71) Applicant: Intel Corporation, Santa Clara, CA (US)

(72) Inventors: Jeremy Ecton, Gilbert, AZ (US); Brandon Christian Marin, Gilbert, AZ (US); Srinivas Venkata Ramanuja Pietambaram, Chandler, AZ (US); Gang Duan, Chandler, AZ (US); Leonel Arana, Phoenix, AZ (US); Benjamin Duong, Phoenix, AZ (US)

(73) Assignee: Intel Corporation, Santa Clara, CA (US)

(21) Appl. No.: 18/756,679

(22) Filed: Jun. 27, 2024

(51) Int. Cl. H01L 23/13; H01L 23/15; H01L 25/065

(52) U.S. Cl. CPC H01L 23/13; H01L 23/15; H01L 25/0655

(57) ABSTRACT

Methods and apparatus to reduce delamination in hybrid cores are disclosed. An example hybrid core of an integrated circuit (IC) package comprises a frame, and a glass panel including a top surface, an edge adjacent the frame, and a tapered surface extending between the edge and the top surface.

### BACKGROUND

In many electronic devices, semiconductor chips and/or dies (e.g., integrated circuit (IC) chips) are connected to larger circuit boards such as motherboards and/or other types of printed circuit boards (PCBs). Frequently, the IC chips are contained within a package that includes a package substrate with one or more redistribution layers containing metal interconnects that enable electrical connections between contacts on the IC chips and corresponding contacts on PCBs.

### BRIEF DESCRIPTION OF THE DRAWINGS

FIG. 1 is a cross-sectional side view of an example integrated circuit (IC) package.

FIG. 2 is a cross-sectional side view of an example hybrid core constructed in accordance with teachings of this disclosure.

FIG. 3 is a flowchart representative of an example method to manufacture an example hybrid core disclosed herein.

FIGS. 4A-4H illustrate various stages in an example process of manufacturing the example hybrid core of FIG. 2.

FIGS. 5A-5B illustrate various stages in an example process of manufacturing the example hybrid core of FIG. 5B.

FIGS. 6A-6F illustrate various stages in an example process of manufacturing the example hybrid cores of FIGS. 6E and 6F.

FIG. 7 illustrates another example IC package including the example hybrid core of FIG. 5B.

FIG. 8 illustrates the example IC package of FIG. 7 including another example hybrid core constructed in accordance with teachings of this disclosure.

FIG. 9 illustrates the example IC package of FIG. 7 including the example hybrid core of FIG. 6F.

FIG. 10 is a top view of a wafer including dies that may be included in an IC package constructed in accordance with teachings disclosed herein.

FIG. 11 is a cross-sectional side view of an IC device that may be included in an IC package constructed in accordance with teachings disclosed herein.

FIG. 12 is a cross-sectional side view of an IC device assembly that may include an IC package constructed in accordance with teachings disclosed herein.

FIG. 13 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

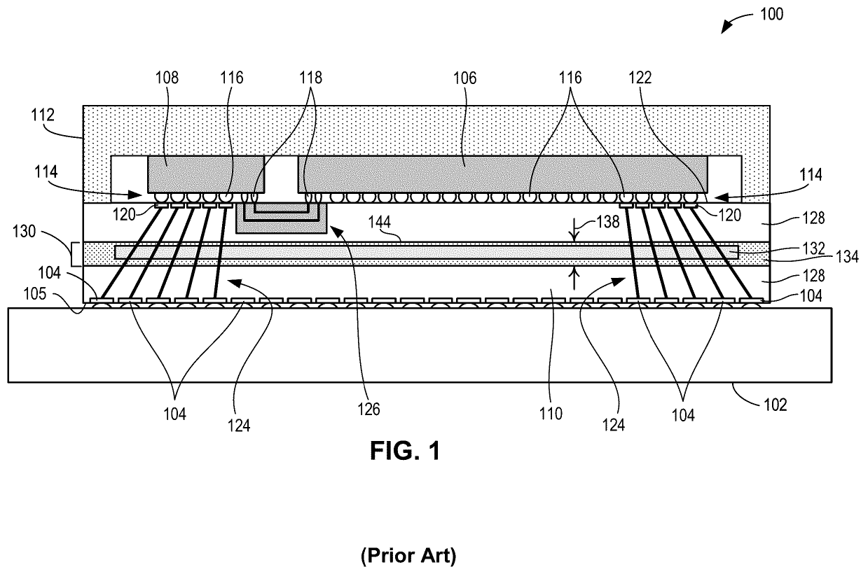

FIG. 1 illustrates an integrated circuit (IC) package 100. In the illustrated example, the IC package 100 is electrically coupled to a circuit board 102 via an array of contact pads or lands 104 on a mounting surface 105 (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is a means for supporting a semiconductor die. While the IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example of FIG. 1, each of the dies 106, 108 is electrically and mechanically coupled to the substrate 110 via corresponding arrays of interconnects 114. In FIG. 1, the interconnects 114 are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or between a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the landing pads 104 on the bottom (external) surface 105 of the substrate 110 (e.g., a surface opposite the inner surface 122) via internal interconnects 124 within the substrate 110. As a result, there is a continuous electrical signal path between the bumps 114 of the dies 106, 108 and the landing pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via a silicon-based interconnect die 126 (e.g., interconnect bridge) embedded in the package substrate 110. As represented in FIG. 1, core bumps 116 are typically larger than bridge bumps 118. In some examples, the interconnect bridge 126 and the associated bridge bumps 118 are omitted. In some examples, the IC package 100 includes additional passive components, such as surface-mount resistors, capacitors, and/or inductors disposed on the bottom (external) surface 105 of the package substrate 110 and/or on the top (inner) surface 122 of the package substrate 110. In some examples, active elements (e.g., transistors) are additionally or alternatively included.

The core 130 of FIG. 1 is a hybrid core 130 having a glass panel 132 surrounded and/or encapsulated by a frame 134. In some examples, hybrid cores having glass panels encapsulated by a frame (e.g., epoxy, dielectric, mold compounds, encapsulants, etc.), can benefit from the strength of the glass while also mitigating against the fragility of the glass. In other words, an example frame made of epoxy, dielectric, mold compound, etc., can protect the glass panel 132 from shear stress, cracking, and/or any other damage from conventional handling equipment. However, hybrid cores are susceptible to delamination under stress. For example, the inner glass panel 132 can delaminate and/or otherwise separate from the frame 134. In some examples, this delamination causes misalignment between components (e.g., vias, traces, etc.) routed through the hybrid core 130 and/or impedes the structural integrity of the IC package 100.

In some examples, the glass panel 132 includes at least one of: aluminosilicate, borosilicate, alumino-borosilicate, silica, and/or fused silica. In some examples, the glass panel 132 includes one or more additives including: aluminum oxide (Al₂O₃), boron trioxide (B₂O₃), magnesia oxide (MgO), calcium oxide (CaO), stoichiometric silicon oxide (SiO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the glass panel 132 includes silicon and oxygen. In some examples, the glass panel 132 includes silicon, oxygen and/or one or more of aluminum, boron, magnesium, calcium, barium, tin, sodium, potassium, strontium, phosphorus, zirconium, lithium, titanium, and/or zinc. In some examples, the glass panel 132 includes at least 23 percent silicon by weight and at least 26 percent oxygen by weight. In some examples, the core is a layer of glass including silicon, oxygen, and aluminum. In some examples, the glass panel 132 includes at least 23 percent silicon by weight, at least 26 percent oxygen by weight, and at least 5 percent aluminum by weight. In some examples, the glass panel 132 is an amorphous solid glass layer. In some examples, the glass panel 132 is a layer of glass that does not include an organic adhesive or an organic material. In some examples, the glass panel 132 is a solid layer of glass having a rectangular shape in plan view. In some examples, the glass panel 132, as a glass substrate, includes at least one glass layer and does not include epoxy and does not include glass fibers (e.g., does not include an epoxy-based prepreg layer with glass cloth). In some examples, the glass panel 132 corresponds to a single piece of glass that extends the full height/thickness of the core. In other examples, the glass panel 132 can be silicon, a dielectric material, and/or any other material(s).

In some examples, the hybrid core 130 has a rectangular shape that is substantially coextensive (e.g., within 2 millimeters (mm)), in plan view, with the layers (e.g., example build-up regions 128) above and/or below the core. In some examples, the hybrid core 130 has a thickness in a range of about 50 micrometers (μm) to about 1.4 mm. In some examples, the hybrid core 130 can be a multi-layer glass substrate (e.g., a coreless substrate), where a glass layer has a thickness in a range of about 25 μm to about 50 μm. In some examples, the hybrid core 130 has dimensions of about 10 mm on a side to about 250 mm on a side (e.g., 10 mm by 10 mm to 250 mm by 250 mm). In some examples, the hybrid core 130 corresponds to a rectangular prism volume with sections (e.g., vias) removed and filled with other materials (e.g., metal).

Among other things, glass cores are advantageous over epoxy-based cores because glass is stiffer and, therefore, provides for greater mechanical support or strength for the package substrate. Thus, glass cores are an example means for strengthening the package substrate. However, glass cores are fragile and/or susceptible to damage under stress. For example, conventional handling equipment (e.g., for use with epoxy-based cores) may not be sensitive or tactile enough to manufacture packages having glass cores.

Examples disclosed herein increase the surface area of an example glass panel to provide greater adhesion between the glass panel and frame. For example, disclosed examples taper and/or otherwise alter the shape of the glass panel to provide a relatively larger surface area to which a frame can bond. Additionally or alternatively, disclosed examples provide trenches, grooves, cavities, etc., in an example glass panel to increase the surface area of the glass panel. Accordingly, an example frame can seep, percolate, and/or extend into such trenches to bond with the glass panel. To that end, disclosed examples provide greater opportunity (by increased surface area) for the frame to effectively bond, grip to, and/or reconstitute with an example glass panel. Thus, disclosed examples can reduce and/or eliminate the delamination between a frame and a glass panel to an associated IC package.

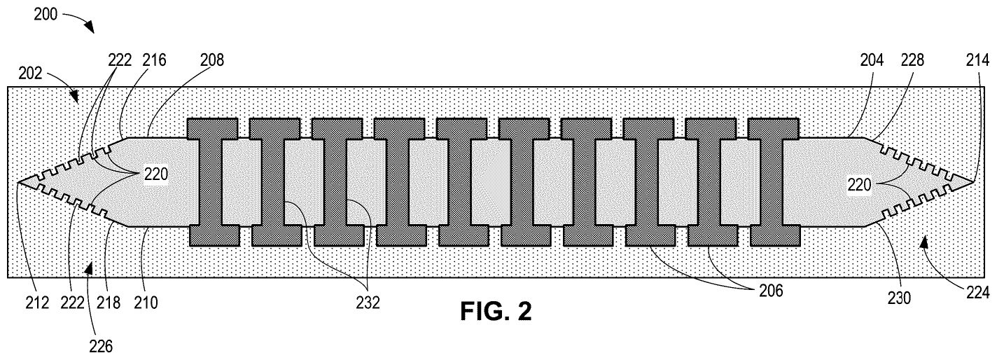

FIG. 2 illustrates an example hybrid core 200 constructed in accordance with teachings disclosed herein. The example hybrid core 200 may be included in the example IC package 100 (e.g., in place of the hybrid core 130) to mitigate delamination. The example hybrid core 200 includes an example frame 202 (e.g., encapsulant, dielectric, mold, etc.), an example glass panel 204, and example interconnects 206. The example glass panel 204 includes an example first surface 208 (e.g., a top surface, etc.) opposing an example second surface 210 (e.g., a bottom surface, etc.). Further, the glass panel 204 includes an example first edge 212 positioned between the first and second surfaces 208, 210 and an example second edge 214 positioned between the first and second surfaces 208, 210. An example first tapered surface 216 extends between the first edge 212 and the first surface 208. Further, an example second tapered surface 218 extends between the first edge 212 and the second surface 210.

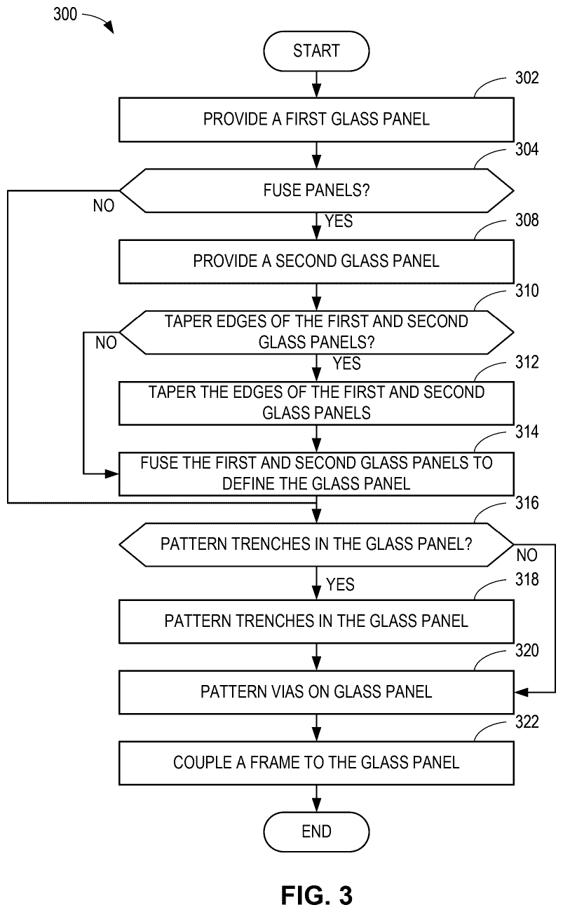

In some examples, the tapered surfaces 216, 218 are angled relative to the at least one of the first surface 208 or the second surface 210. For example, the first tapered surface 216 may be angled about 45 degrees (e.g., +/−2 degrees) from the first surface 208. However, the first tapered surface 216 may be positioned at an angle in range from 0 degrees to 90 degrees (e.g., +/−5 degrees) relative to the first surface 208. In the illustrated example of FIG. 2, the example first tapered surface 216 and the second tapered surface 218 have about the same length (e.g., +/−2 micrometers (μm)). In other examples, the first tapered surface 216 and the second tapered surface 218 have different lengths. In the example of FIG. 2, the first and second tapered surfaces 216, 218 converge at the first edge 212 to define a generally triangular shape. In other examples, the first edge 212 is an edge surface extending between the first tapered surface 216 and the second tapered surface 218. For example, the first edge 212, the first tapered surface 216, and the second tapered surface 218 define a generally trapezoidal and/or rectangular shape, as described in detail in connection with the process of FIG. 3.

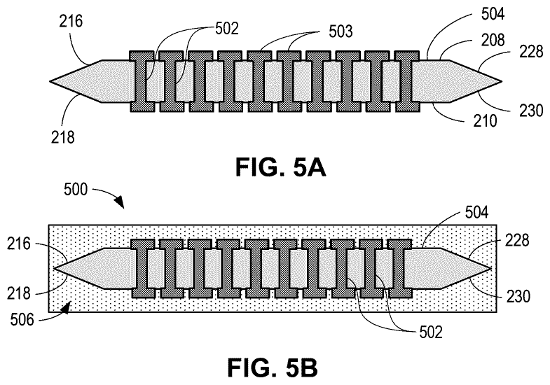

In the illustrated example of FIG. 2, the example first and second tapered surfaces 216, 218, include a pattern, array, series, plurality, etc., of example trenches 220 (e.g., cavities, grooves, etc.). In the illustrated example of FIG. 2, the trenches 220 are even distributed along the first and second tapered surfaces 216, 218). In other examples, the trenches 220 are unevenly (e.g., irregularly, randomly, non-uniformly, etc.) distributed on one or both of the tapered surfaces 216, 218. The example trenches 220 may be cavities, grooves, etc., in the glass panel 204. Put differently, portions of the example glass panel 204 are removed (e.g., via etching, via lithography, via mechanical cutting, via laser cutting, Bessel beams, etc.) to define the trenches 220. In the illustrated example of FIG. 2, the example trenches 220 include a generally rectangular cross-section. In other examples, the example trenches 220 can include a cross-section of any suitable shape (e.g., square, triangular, oval, circular, trapezoidal, etc.). In some examples, the trenches 220 extend into the glass panel 204 to a depth between 0.5 μm to 25 μm. The example first tapered surface 216 and/or the example second tapered surface 218 may include any number of the trenches 220 (e.g., 1 trench, 2 trenches, etc.). In some examples, the first tapered surface 216 and/or the second tapered surface 218 include no trenches. An example hybrid core including tapered surfaces that do not include trenches is described below in conjunction with FIGS. 5A and 5B.

The edges 212, 214 of this example are adjacent to the frame 202. For example, the edges 212, 214 may be in contact (e.g., abutting) with the frame 202. Similarly, the first and second surfaces 208, 210 of this example are in contact with the frame 202. In some examples, the frame 202 encapsulates (e.g., is shaped to, is fitted to, etc.) the glass panel 204. For example, the frame 202 includes a tapered surface aligned with and in contact with the first tapered surface 216 and another tapered surface aligned with and in contact with the second tapered surface 218. As shown in FIG. 2, at least some of the example frame 202 extends into the trenches 220 of glass panel 204. For example, the frame 202 includes example anchors 222 (e.g., bosses, protrusions, etc.) that extend from the frame 202 towards the glass panel 204. That is, in the illustrated example of FIG. 2, each of the anchors 222 extends into (e.g., partially into, fully into, etc.) a corresponding one of the trenches 220. As such, the example trenches 220 are shaped to receive the anchors 222. The terms “anchor” and “microanchor” are used interchangeably.

As previously mentioned, the example glass panel 204 includes the second edge 214 positioned on an example first side 224 of the glass panel 204 (opposing an example second side 226 of the glass panel 204 that includes the first edge 212). Similar to the second side 226, the first side 224 includes an example third tapered surface 228 that extends from the second edge 214 to the first surface 208. Further, the first side 224 includes an example fourth tapered surface 230 that extends from the second edge 214 to the second surface 210. In the illustrated example of FIG. 2, the tapered surfaces 228, 230 include ones of the trenches 220, which receive corresponding ones of the anchors 222.

In the illustrated example of FIG. 2, the glass panel 204 includes example vias 232 that extend therethrough from the first surface 208 to the second surface 210. The example vias 232 enable electrical signals and power to be routed through the glass panel 204. The example vias 232 are positioned between the edges 212, 214 of the glass panel 204. Accordingly, in the example of FIG. 2, the ones of the trenches 220 are disposed between the vias 232 (e.g., at least one of the vias 232) and the first edge 212 and ones of the trenches are disposed between the vias 232 and the second edge 214.

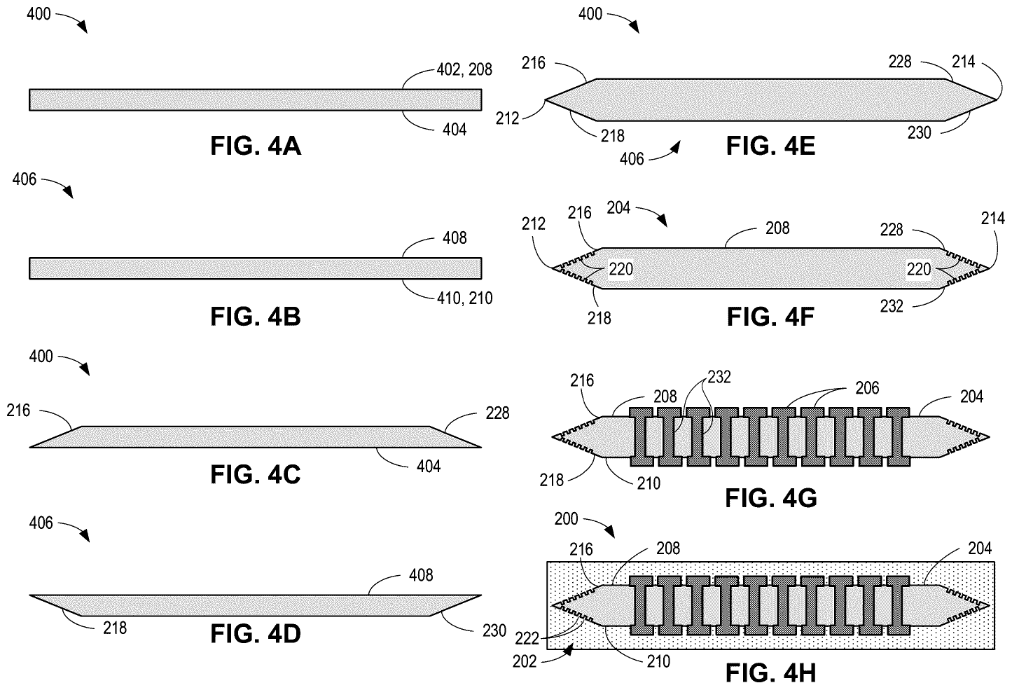

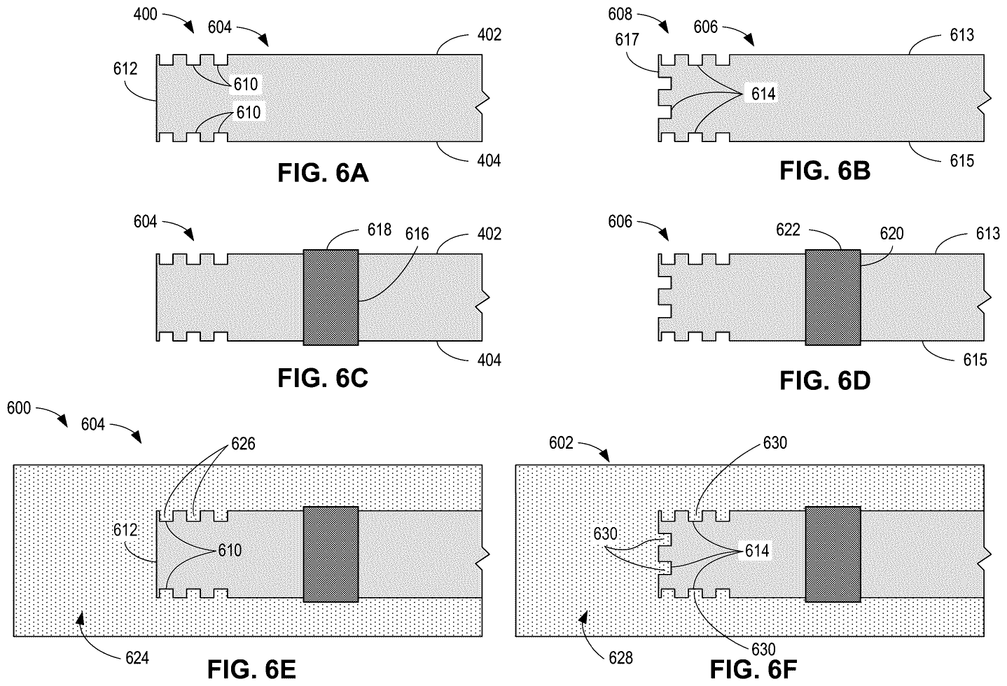

FIG. 3 is a flowchart representative of an example method 300 to produce the example hybrid core 200 of FIGS. 2 and 4H, an example hybrid core 500 of FIG. 5B, an example hybrid core 600 of FIG. 6E, and/or an example hybrid core 602 of FIG. 6F. FIGS. 4A-4H represent the example hybrid core 200 of FIGS. 2 and 4H at various stages during the example process described in FIG. 3. FIGS. 4A-4E and 5A-5B represent the example hybrid core 500 of FIG. 5B at various stages during the example process described in FIG. 3. FIGS. 4A, 6A, 6C, and 6E represent the example hybrid core 600 of FIG. 6E at various stages during the example process described in FIG. 3. FIGS. 4A, 6B, 6D, and 6F represent the example hybrid core 600 of FIG. 6F at various stages during the example process described in FIG. 3. In some examples, some or all of the operations outlined in the example method 300 of FIG. 3 are performed by fabrication equipment that is programmed to perform the operations. Although the example method of manufacture is described with reference to the flowchart illustrated in FIG. 3 and the stages of FIGS. 4A-6F, many other methods and/or stages may alternatively be used. For example, the order of execution of the blocks may be changed, and/or some of the blocks described may be combined, divided, re-arranged, omitted eliminated, and/or implemented in any other way. Further, in some examples, additional operations can be performed before, between, and/or after any of the blocks represented in the illustrated example.

Turning to FIG. 3, the example process begins at block 302 at which an example first glass panel is provided. As shown in FIG. 4A, an example first glass panel 400 is provided. The example first glass panel 400 includes example opposing surfaces 402, 404. In some examples, the surface 402 is a top surface (e.g., the first surface 208) and the surface 404 is an example first mounting surface that is opposite the surface 402.

At block 304, it is determined whether to fuse panels. If panels are not to be fused, the process proceeds to block 316, as discussed below in connection with FIGS. 6A-6F. If example panels are to be fused, the process proceeds to block 308. In the example process illustrated by FIGS. 4A-4H and 5A-5B, example panels are to be fused. In such examples, the process proceeds to block 308.

At block 308, an example second glass panel is provided. As shown in in the illustrated example of FIG. 4B, an example second glass panel 406 is provided. The example second glass panel 406 includes example opposing surfaces 408, 410. In this example, the surface 410 is a bottom surface (e.g., the second surface 210) and the surface 408 is an example second mounting surface that is opposite the surface 410.

At block 310, it is determined whether to taper the edge(s) of the first and second glass panels. If the edge(s) are not to be tapered, the process proceeds to block 314. If the edge(s) are to be tapered, the process proceeds to block 312. In the example process illustrated by FIGS. 4A-4H and 5A-5B, example edges are to be tapered. In such examples, the process proceeds to block 312.

At block 312, the example edges of the first and second panels are to be tapered. As shown in FIG. 4C, an example first edge of the first glass panel 400 is tapered (e.g., the third tapered surface 228) and an example second edge of the first glass panel 400 is tapered (e.g., the first tapered surface 216). Further, as shown in FIG. 4D, an example third edge of the second glass panel 406 is tapered (e.g., the second tapered surface 218) and an example fourth edge of the second glass panel 406 is tapered (e.g., the fourth tapered surface 230). In some examples, the edges of the first and second panels 400, 406 are tapered to increase the surface areas of the respective first and second panels 400, 406.

At block 314, the example first and second panels are fused. As shown in FIG. 4E, the example first and second glass panels 400, 406 are fused (e.g., bonded, coupled, etc.). For example, the first mounting surface 404 is coupled to the second mounting surface 408 via a glass fusion technique. In some examples, the first and second glass panels 400, 406 are fused with a chemical adhesion, such as bond fill. As shown in FIG. 4E, the example first and second tapered surfaces 216, 218 converge at the first edge 212. Further, the example third and fourth tapered surfaces 228, 230 converge at the second edge 214.

At block 316, it is determined whether to pattern trenches in the glass panel. If no example trenches are to be patterned, then the process proceeds to block 320, as described in connection with FIGS. 5A and 5B. If example trenches are to be patterned, then the process proceeds to block 318. In the example of FIGS. 4A-4H, example trenches are to be patterned in the glass panel. In such examples, the process proceeds to block 318.

At block 318, example trenches are patterned in the glass panel. As shown in FIG. 4F, the example trenches 220 are patterned in the glass panel 204. In some examples, the trenches 220 are patterned in the glass panel 204 to increase the surface area of the glass panel 204. For example, the trenches 220 are patterned in the first tapered surface 216, the second tapered surface 218, the third tapered surface 228, and the fourth tapered surface 230. In some examples, at least one of the tapered surfaces 216, 218, 228, 230 does not include the example trenches 220. In the example of FIG. 4F, the example trenches 220 are distributed along the tapered surfaces 216, 218, 228, 230. For example, the trenches 220 are distributed along the first tapered surface 216 from the first edge 212 to the first surface 208. In other examples, the trenches 220 are distributed partially along the first tapered surface 216 (e.g., in an example first direction from the first edge 212 to the first surface 208, in an example second direction from the first surface 208 to the first edge 212, etc.).

At block 320, example vias are patterned on the glass panel. As shown in FIG. 4G, the example vias 232 are patterned on the glass panel 204. For example, the vias 232 extend from the first surface 208 to the second surface 210. Further, as shown in FIG. 4G, the example interconnects 206 are routed through the vias 232.

At block 322, an example frame is coupled to the glass panel. As shown in FIG. 4H, the frame 202 is coupled to the glass panel 204. The example frame 202 includes the anchors 222 that extend from the frame 202 towards the glass panel 204. More particularly, the example anchors 222 can extend at least partially into corresponding ones of the trenches 220. As such, the example trenches 220 are receiving the anchors 222. Thus, the example frame 202 is coupled to glass panel 204 by the anchors 222 extending into and/or adhering to surfaces that define the trenches 220. Put differently, the example frame 202 is reconstituted with the glass panel 204. As shown in FIG. 4H, the hybrid core 200 is defined.

Returning to block 316, if it is determined that example trenches are not to be patterned in the glass panel, then the process proceeds to block 320 with the subsequent stage(s) of fabrication represented by FIGS. 5A and 5B. At block 320, example vias are patterned in the example glass panel. As shown in FIG. 5A, example vias 502 are patterned in an example glass panel 504. For example, the vias 502 extend from the first surface 208 to the second surface 210. Further, example interconnects 503 are routed through the vias 502. The example glass panel 504 of FIGS. 5A and 5B is similar to the example glass panel 204 of FIGS. 2 and 4H. However, the example glass panel 504 does not include the example trenches 220 in any of the example first, second, third, or fourth tapered surfaces 216, 218, 228, 230. In some examples, the first, second, third, and/or fourth tapered surfaces 216, 218, 228, 230 in the glass panel 504 are smooth. In some examples, the first, second, third, and/or fourth tapered surface 216, 218, 228, 230 in the glass panel 504 includes a surface treatment (e.g., roughened).

At block 322, an example frame is coupled to the glass panel. As shown in FIG. 5B, an example frame 506 is coupled to the glass panel 504. The example frame 506 of FIG. 5B is similar to the example frame 202 of FIGS. 2 and 4H. However, the example frame 506 does not include example anchors that extend from the frame 506 into corresponding trenches in the glass panel 504. Alternatively, the example frame 506 is coupled directly to the first, second, third, and fourth tapered surfaces 216, 218, 228, 230. As shown in FIG. 5B, the example hybrid core 500 is defined. The example hybrid core 500 may be included in the example IC package 100 (in place of the hybrid core 130) to reduce the likelihood of delamination of the frame 506 and glass panel 504.

Returning to block 304, if it is determined to not fuse panels, then the process proceeds to block 316 with the subsequent stage(s) of fabrication represented by FIGS. 6A-6F. At block 316, it is determined whether to pattern trenches in the glass panel. If no example trenches are to be patterned (block 316), then the process proceeds to block 320. If example trenches are to be patterned (block 316), then the process proceeds to block 318. In the example of FIGS. 6A-6F, example trenches are to be patterned in the glass panel. In such examples, the process proceeds to block 318. As shown in FIG. 6A, the first glass panel 400 is provided. In particular, an example portion 604 of the first glass panel 400 is shown. In FIG. 6B, an example portion 606 of an example glass panel 608 is shown. In some examples, the portions 604, 606 are included in a same glass panel (e.g., the first glass panel 400, the glass panel 608, etc.). For example, the first glass panel 400 can include the portion 604 on an example first side and the portion 606 on an example second side. For purposes of explanation, the portions 604, 606 reside on different example glass panels.

At block 318, example trenches are patterned in the glass panel. As shown in FIG. 6A, example trenches 610 are patterned in the first glass panel 400. For example, the trenches 610 are patterned on the surfaces 402, 404 of the first glass panel 400. At least one of the example trenches 610 is adjacent to an example edge surface 612. In the example of FIG. 6A, the edge surface 612 (extending from the surface 402 to the surface 404) does not include any example trenches. In some examples, the edge surface 612 includes a surface treatment or is smooth. As shown in FIG. 6B, example trenches 614 are patterned on example opposing surfaces 613, 615 of the glass panel 608. An example edge surface 617 includes the trenches 614. In the illustrated example of FIG. 6A, the edge surface 617 extends from the surface 613 to the surface 615.

At block 320, example vias are patterned on the glass panel. As shown in FIG. 6C, an example via 616 is patterned in the portion 604. The example via 616 extends from the surface 402 to the surface 404. Further, an example interconnect 618 extends through the via 616. As shown in FIG. 6D, an example via 620 is patterned in the portion 606. The example via 620 extends from the surface 613 to the surface 615. Further, an example interconnect 622 extends through the via 620.

At block 322, an example frame is coupled to the glass panel. As shown in FIG. 6E, an example frame 624 is coupled to the portion 604 of the first glass panel 400. The example frame 624 includes example anchors 626 that extend from the frame 624 towards the first glass panel 400. More particularly, the example anchors 626 can extend at least partially into corresponding ones of the trenches 610. As such, the example trenches 610 are shaped and/or fitted to receive the anchors 626. Thus, the example frame 624 is coupled to the first glass panel 400 by (i) the anchors 626 extending into and/or adhering to surfaces that define the trenches 610 and (ii) the frame 624 adhering to the edge surface 612. As shown in FIG. 6E, the hybrid core 600 is defined. The example hybrid core 600 may be included in the example IC package 100 (in place of the hybrid core 130) to mitigate the damaging effects of delamination.

Further, as shown in FIG. 6F, an example frame 628 is coupled to the glass panel 608. The example frame 628 includes example anchors 630 that extend from the frame 628 towards the glass panel 608. More particularly, the example anchors 630 can extend at least partially into corresponding ones of the trenches 614. As such, the example trenches 614 are shaped and/or fitted to receive the anchors 630. Thus, the example frame 628 is coupled to the portion 606 of the glass panel 608 by the anchors 630 extending into and/or adhering to surfaces that define the trenches 614. As shown in FIG. 6F, the hybrid core 602 is defined. The example hybrid core 602 may be included in the example IC package 100 (in place of the hybrid core 130) to mitigate the damaging effects of delamination.

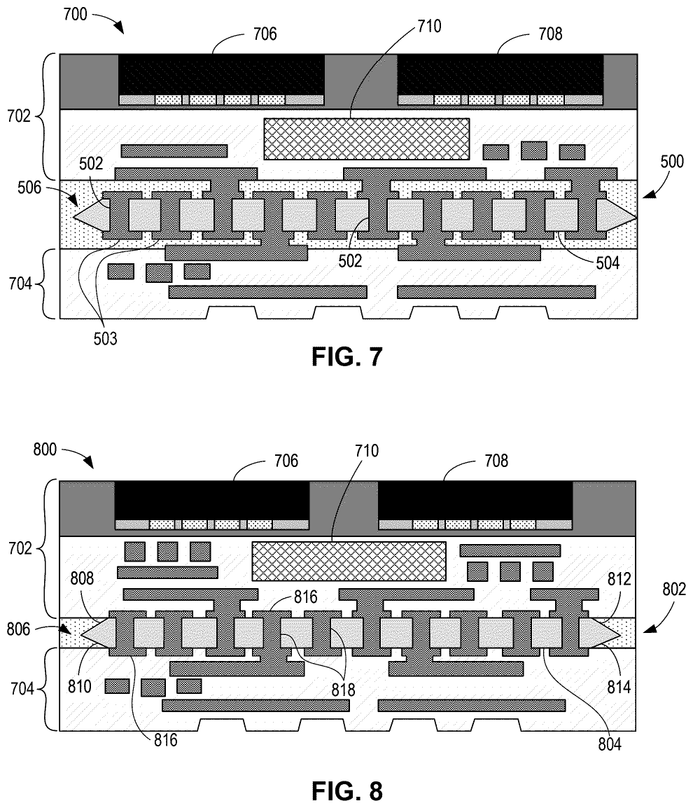

FIG. 7 is an example IC package 700 including example build-up regions 702, 704, example dies 706, 708, an example interconnect bridge 710, and the example hybrid core 500 of FIG. 5B. The example hybrid core 500 separates the example build-up regions 702, 704. However, the example frame 506 surrounds the glass panel 504 such that the glass panel 504 is separated from the build-up regions 702, 704. As such, the example frame 506 is in contact with the build-up regions 702, 704. Further, the example interconnects 503 extend between the build-up regions 702, 704 through ones of the vias 502. As such, the example build-up region 704 may be electrically coupled to the dies 706, 708 via the interconnects 503 and the build-up region 702. As shown in FIG. 7, at least some of the interconnects 503 are in contact with the frame 506.

FIG. 8 is an example IC package 800 including an example hybrid core 802. In some examples, the hybrid core 802 may be included in the example IC package 100 (in place of the hybrid core 130) to mitigate the damaging effects of delamination. The example IC package 800 of FIG. 8 is similar to the example IC package 700 of FIG. 7. However, the example IC package 800 includes the hybrid core 802. The example hybrid core 802 of FIG. 8 is similar to the hybrid core 500 of FIGS. 5B and 7. However, the example hybrid core 802 includes a glass panel 804 that is in contact with the build-up region 702 and the build-up region 704. Further, the hybrid core 802 includes an example frame 806 that is positioned adjacent example tapered surfaces 808, 810, 812, 814 of the glass panel 804. However, the example frame 806 does not separate the glass panel 804 from either of the build-up regions 702, 704. As such, the example glass panel 804 separates the build-up region 702 from the build-up region 704. Further, example interconnects 816 (extending through example vias 818 in the glass panel 804) extend between the build-up regions 702, 704. However, the example interconnects 816 do not directly contact the frame 806 (based on the glass panel 804 being in direct contact with the build-up regions 702, 704).

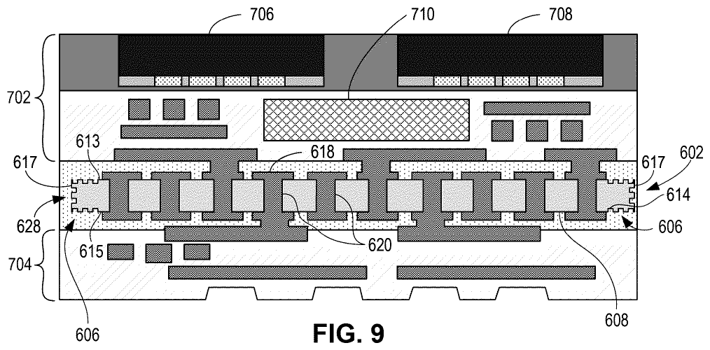

FIG. 9 is an example IC package 900 including the hybrid core 602. The example IC package 900 of FIG. 9 is similar to the example IC package 700 of FIG. 7. However, the example IC package 900 includes the hybrid core 602. In this example, the hybrid core 602 includes the glass panel 608 having two instances of the portion 606 (on opposing sides of the glass panel 608). As such, the example glass panel 608 includes the trenches 614 on the surfaces 613, 615 and the edge surfaces 617. Further, the example hybrid core 602 includes multiple ones of the via 620 and the interconnect 622.

In the example of FIG. 9, the example frame 628 surrounds the glass panel 608 such that the glass panel 608 is separated from the build-up regions 702, 704. However, the example hybrid core 602 of FIG. 9 may be modified such that the glass panel 608 is in contact with the build-up regions 702, 704. For example, at least some of the frame 628 may be removed such that the glass panel 608 separates the build-up region 702 from the build-up region 704.

In the examples of FIGS. 7, 8, and 9, one glass panel is shown (e.g., the glass panel 504 in the hybrid core 500, the glass panel 804 in the hybrid core 802, the glass panel 608 the hybrid core 602). However, any number of glass panels may be encapsulated by the respective frames (e.g., the frame 506, the frame 806, the frame 628, etc.). For example, the IC package of FIG. 7 may include two example glass panels 504 spaced apart from one another within the frame 506. Additionally or alternatively, example frames disclosed herein can encapsulate multiple glass panels of different types. For example, an example frame disclosed herein can encapsulate the glass panel 504 and the glass panel 608, wherein the glass panels 504, 608 are spaced apart from one another within the frame. Thus, examples disclosed herein can include any number and/or any combination of glass panels encapsulated by example frames disclosed herein.

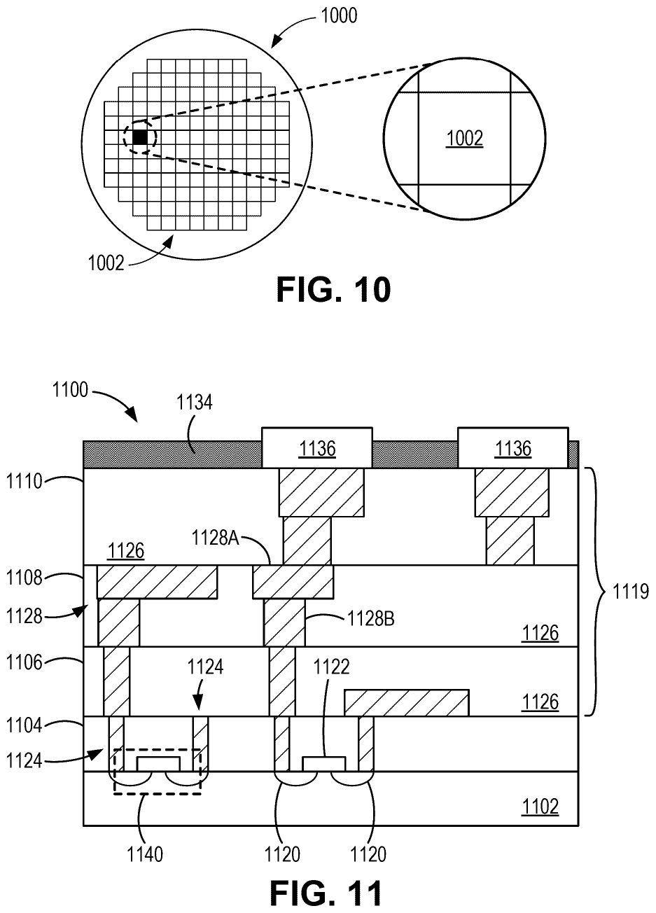

The example hybrid core 200 of FIGS. 2 and 4H, the example hybrid core 500 of FIG. 5B, the example hybrid core 600 of FIG. 6E, the example hybrid core 602 of FIG. 6F, and/or the example hybrid core 802 of FIG. 8 disclosed herein may be included in any suitable electronic component. FIGS. 10-13 illustrate various examples of apparatus that may include the example hybrid core 200 of FIGS. 2 and 4H, the example hybrid core 500 of FIG. 5B, the example hybrid core 600 of FIG. 6E, the example hybrid core 602 of FIG. 6F, and/or the example hybrid core 802 of FIG. 8 disclosed herein.

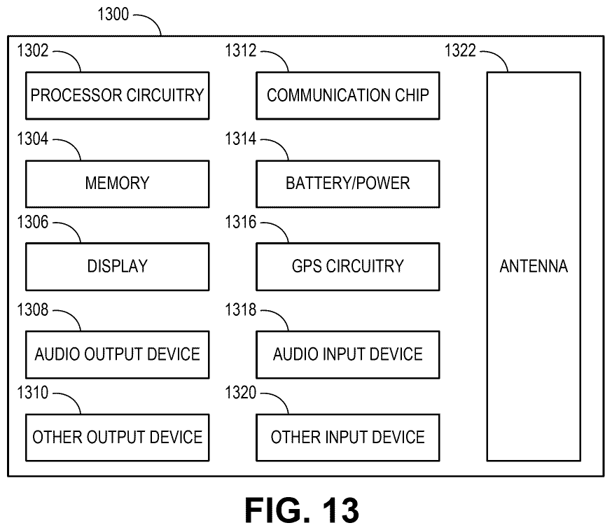

FIG. 10 is a top view of a wafer 1000 and dies 1002 that may be included in an IC package that includes one or more hybrid cores 200, 500, 600, 602, 802 (e.g., as discussed with reference to FIG. 1) in accordance with any of the examples disclosed herein. The wafer 1000 includes semiconductor material and one or more dies 1002 having circuitry. Each of the dies 1002 may be a repeating unit of a semiconductor product. After the fabrication of the semiconductor product is complete, the wafer 1000 may undergo a singulation process in which the dies 1002 are separated from one another to provide discrete “chips.” The die 1002 includes one or more transistors (e.g., some of the transistors 1140 of FIG. 11, discussed below), supporting circuitry to route electrical signals to the transistors, passive components (e.g., traces, resistors, capacitors, inductors, and/or other circuitry), and/or any other components. In some examples, the die 1002 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1002. For example, a memory array of multiple memory circuits may be formed on a same die 1002 as programmable circuitry (e.g., the processor circuitry 1302 of FIG. 13) and/or other logic circuitry. Such memory may store information for use by the programmable circuitry. The example IC package 100 including any one of the hybrid cores 200, 500, 600, 602, 802 disclosed herein may be manufactured using a die-to-wafer assembly technique in which some dies are attached to a wafer 1000 that includes others of the dies, and the wafer 1000 is subsequently singulated.

FIG. 11 is a cross-sectional side view of an IC device 1100 that may be included in the IC package 100 (including any one of the hybrid cores 200, 500, 600, 602, 802 disclosed herein) (e.g., in any one of the dies 106, 108). One or more of the IC devices 1100 may be included in one or more dies 1002 (FIG. 10). The IC device 1100 may be formed on a die substrate 1102 (e.g., the wafer 1000 of FIG. 10) and may be included in a die (e.g., the die 1002 of FIG. 10). The die substrate 1102 may be a semiconductor substrate including semiconductor materials including, for example, n-type or p-type materials systems (or a combination of both). The die substrate 1102 may include, for example, a crystalline substrate formed using a bulk silicon or a silicon-on-insulator (SOI) substructure. In some examples, the die substrate 1102 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1102. Although a few examples of materials from which the die substrate 1102 may be formed are described here, any material that may serve as a foundation for an IC device 1100 may be used. The die substrate 1102 may be part of a singulated die (e.g., the dies 1002 of FIG. 10) or a wafer (e.g., the wafer 1000 of FIG. 10).

The IC device 1100 may include one or more device layers 1104 disposed on and/or above the die substrate 1102. The device layer 1104 may include features of one or more transistors 1140 (e.g., metal oxide semiconductor field-effect transistors (MOSFETs)) formed on the die substrate 1102. The device layer 1104 may include, for example, one or more source and/or drain (S/D) regions 1120, a gate 1122 to control current flow between the S/D regions 1120, and one or more S/D contacts 1124 to route electrical signals to/from the S/D regions 1120. The transistors 1140 may include additional features not depicted for the sake of clarity, such as device isolation regions, gate contacts, and the like. The transistors 1140 are not limited to the type and configuration depicted in FIG. 11 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1140 may include a gate 1122 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1140 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1140 along the source-channel-drain direction, the gate electrode may include a U-shaped structure that includes a bottom portion substantially parallel (e.g., within 5 degrees) to the surface of the die substrate 1102 and two sidewall portions that are substantially perpendicular (e.g., within 5 degrees) to the top surface of the die substrate 1102. In other examples, at least one of the metal layers that form the gate electrode may be a planar layer that is substantially parallel to the top surface of the die substrate 1102 and does not include sidewall portions substantially perpendicular to the top surface of the die substrate 1102. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1120 may be formed within the die substrate 1102 adjacent to the gate 1122 of corresponding transistor(s) 1140. The S/D regions 1120 may be formed using an implantation/diffusion process or an etching/deposition process, for example. In the former process, dopants such as boron, aluminum, antimony, phosphorous, or arsenic may be ion-implanted into the die substrate 1102 to form the S/D regions 1120. An annealing process that activates the dopants and causes them to diffuse farther into the die substrate 1102 may follow the ion-implantation process. In the latter process, the die substrate 1102 may first be etched to form recesses at the locations of the S/D regions 1120. An epitaxial deposition process may then be carried out to fill the recesses with material that is used to fabricate the S/D regions 1120. In some implementations, the S/D regions 1120 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1120 may be formed using one or more alternate semiconductor materials such as germanium or a group III-V material or alloy. In further examples, one or more layers of metal and/or metal alloys may be used to form the S/D regions 1120.

Electrical signals, such as power and/or input/output (I/O) signals, may be routed to and/or from the devices (e.g., transistors 1140) of the device layer 1104 through one or more interconnect layers disposed on the device layer 1104 (illustrated in FIG. 11 as interconnect layers 1106-1110). For example, electrically conductive features of the device layer 1104 (e.g., the gate 1122 and the S/D contacts 1124) may be electrically coupled with the interconnect structures 1128 of the interconnect layers 1106-1110. The one or more interconnect layers 1106-1110 may form a metallization stack (also referred to as an “ILD stack”) 2019 of the IC device 1100.

The interconnect structures 1128 may be arranged within the interconnect layers 1106-1110 to route electrical signals according to a wide variety of designs (in particular, the arrangement is not limited to the particular configuration of interconnect structures 1128 depicted in FIG. 11). Although a particular number of interconnect layers 1106-1110 is depicted in FIG. 11, examples of the present disclosure include IC devices having more or fewer interconnect layers than depicted.

In some examples, the interconnect structures 1128 may include lines 1128a and/or vias 1128b filled with an electrically conductive material such as a metal. The lines 1128a may be arranged to route electrical signals in a direction of a plane that is substantially parallel with a surface of the die substrate 1102 upon which the device layer 1104 is formed. For example, the lines 1128a may route electrical signals in a direction in and/or out of the page from the perspective of FIG. 11. The vias 1128b may be arranged to route electrical signals in a direction of a plane that is substantially perpendicular to the surface of the die substrate 1102 upon which the device layer 1104 is formed. In some examples, the vias 1128b may electrically couple lines 1128a of different interconnect layers 1106-1110 together.

The interconnect layers 1106-1110 may include a dielectric material 1126 disposed between the interconnect structures 1128, as shown in FIG. 11. In some examples, the dielectric material 1126 disposed between the interconnect structures 1128 in different ones of the interconnect layers 1106-1110 may have different compositions; in other examples, the composition of the dielectric material 1126 between different interconnect layers 1106-1110 may be the same.

A first interconnect layer 1106 (referred to as Metal 1 or “M1”) may be formed directly on the device layer 1104. In some examples, the first interconnect layer 1106 may include lines 1128a and/or vias 1128b, as shown. The lines 1128a of the first interconnect layer 1106 may be coupled with contacts (e.g., the S/D contacts 1124) of the device layer 1104.

A second interconnect layer 1108 (referred to as Metal 2 or “M2”) may be formed directly on the first interconnect layer 1106. In some examples, the second interconnect layer 1108 may include vias 1128b to couple the lines 1128a of the second interconnect layer 1108 with the lines 1128a of the first interconnect layer 1106. Although the lines 1128a and the vias 1128b are structurally delineated with a line within each interconnect layer (e.g., within the second interconnect layer 1108) for the sake of clarity, the lines 1128a and the vias 1128b may be structurally and/or materially contiguous (e.g., simultaneously filled during a dual-damascene process) in some examples.

A third interconnect layer 1110 (referred to as Metal 3 or “M3”) (and additional interconnect layers, as desired) may be formed in succession on the second interconnect layer 1108 according to similar techniques and/or configurations described in connection with the second interconnect layer 1108 or the first interconnect layer 1106. In some examples, the interconnect layers that are “higher up” in the metallization stack 1119 in the IC device 1100 (i.e., further away from the device layer 1104) may be thicker.

The IC device 1100 may include a solder resist material 1134 (e.g., polyimide or similar material) and one or more conductive contacts 1136 formed on the interconnect layers 1106-1110. In FIG. 11, the conductive contacts 1136 are illustrated as taking the form of bond pads. The conductive contacts 1136 may be electrically coupled with the interconnect structures 1128 and configured to route the electrical signals of the transistor(s) 1140 to other external devices. For example, solder bonds may be formed on the one or more conductive contacts 1136 to mechanically and/or electrically couple a chip including the IC device 1100 with another component (e.g., a circuit board). The IC device 1100 may include additional or alternate structures to route the electrical signals from the interconnect layers 1106-1110; for example, the conductive contacts 1136 may include other analogous features (e.g., posts) that route the electrical signals to external components.

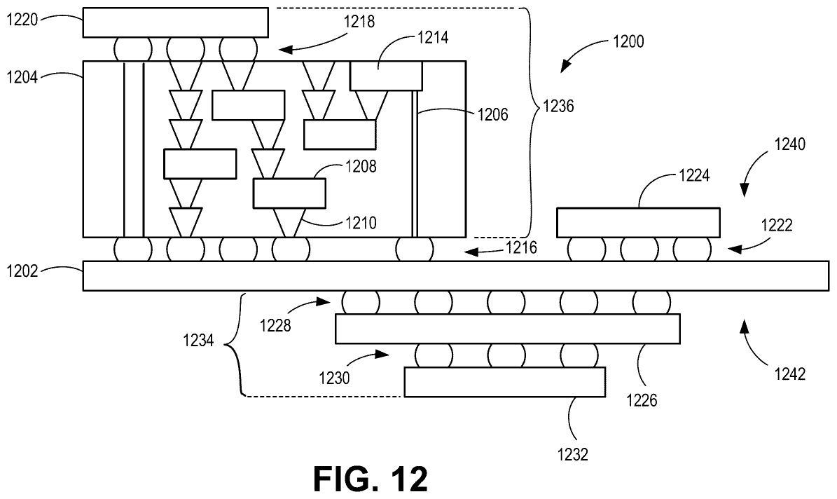

FIG. 12 is a cross-sectional side view of an IC device assembly 1200 that may include the any one of the hybrid cores 200, 500, 600, 602, 802 disclosed herein. In some examples, the IC device assembly corresponds to the IC package 100 (including any one of the hybrid cores 200, 500, 600, 602, 802). The IC device assembly 1200 includes a number of components disposed on a circuit board 1202 (which may be, for example, a motherboard). The IC device assembly 1200 includes components disposed on a first face 1240 of the circuit board 1202 and an opposing second face 1242 of the circuit board 1202; generally, components may be disposed on one or both faces 1240 and 1242. Any of the IC packages discussed below with reference to the IC device assembly 1200 may take the form of the example IC package 100 (any one of the hybrid cores 200, 500, 600, 602, 802) of FIG. 1, the example IC package 700 of FIG. 7, the example IC package 800 of FIG. 8, and/or the example IC package 900 of FIG. 9.

In some examples, the circuit board 1202 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1202. In other examples, the circuit board 1202 may be a non-PCB substrate.

The IC device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), male and female portions of a socket, an adhesive, an underfill material, and/or any other suitable electrical and/or mechanical coupling structure.

The package-on-interposer structure 1236 may include an IC package 1220 coupled to an interposer 1204 by coupling components 1218. The coupling components 1218 may take any suitable form for the application, such as the forms discussed above with reference to the coupling components 1216. Although a single IC package 1220 is shown in FIG. 12, multiple IC packages may be coupled to the interposer 1204; indeed, additional interposers may be coupled to the interposer 1204. The interposer 1204 may provide an intervening substrate used to bridge the circuit board 1202 and the IC package 1220. The IC package 1220 may be or include, for example, a die (the die 1002 of FIG. 10), an IC device (e.g., the IC device 1100 of FIG. 11), or any other suitable component. Generally, the interposer 1204 may spread a connection to a wider pitch or reroute a connection to a different connection. For example, the interposer 1204 may couple the IC package 1220 (e.g., a die) to a set of BGA conductive contacts of the coupling components 1216 for coupling to the circuit board 1202. In the example illustrated in FIG. 12, the IC package 1220 and the circuit board 1202 are attached to opposing sides of the interposer 1204; in other examples, the IC package 1220 and the circuit board 1202 may be attached to a same side of the interposer 1204. In some examples, three or more components may be interconnected by way of the interposer 1204.

In some examples, the interposer 1204 may be formed as a PCB, including multiple metal layers separated from one another by layers of dielectric material and interconnected by electrically conductive vias. In some examples, the interposer 1204 may be formed of an epoxy resin, a fiberglass-reinforced epoxy resin, an epoxy resin with inorganic fillers, a ceramic material, or a polymer material such as polyimide. In some examples, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through-silicon vias (TSVs) 1206. The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The IC device assembly 1200 may include an IC package 1224 coupled to the first face 1240 of the circuit board 1202 by coupling components 1212. The coupling components 1212 may take the form of any of the examples discussed above with reference to the coupling components 1216, and the IC package 1224 may take the form of any of the examples discussed above with reference to the IC package 1220.

The IC device assembly 1200 illustrated in FIG. 12 includes a package-on-package structure 1234 coupled to the second face 1242 of the circuit board 1202 by coupling components 1228. The package-on-package structure 1234 may include a first IC package 1226 and a second IC package 1232 coupled together by coupling components 1230 such that the first IC package 1226 is disposed between the circuit board 1202 and the second IC package 1232. The coupling components 1228, 1230 may take the form of any of the examples of the coupling components 1216 discussed above, and the IC packages 1226, 1232 may take the form of any of the examples of the IC package 1220 discussed above. The package-on-package structure 1234 may be configured in accordance with any of the package-on-package structures known in the art.

FIG. 13 is a block diagram of an example electrical device 1300 that may include one or more of the example hybrid cores 200, 500, 600, 602, 802. For example, any suitable ones of the components of the electrical device 1300 may include one or more of the device assemblies 1200, IC devices 1100, or dies 1002 disclosed herein, and may be arranged in one or more of the example hybrid cores 200, 500, 600, 602, 802. A number of components are illustrated in FIG. 13 as included in the electrical device 1300, but any one or more of these components may be omitted or duplicated, as suitable for the application. In some examples, some or all of the components included in the electrical device 1300 may be attached to one or more motherboards. In some examples, some or all of these components are fabricated onto a single system-on-a-chip (SoC) die.

Additionally, in various examples, the electrical device 1300 may not include one or more of the components illustrated in FIG. 13, but the electrical device 1300 may include interface circuitry for coupling to the one or more components. For example, the electrical device 1300 may not include a display 1306, but may include display interface circuitry (e.g., a connector and driver circuitry) to which a display 1306 may be coupled. In another set of examples, the electrical device 1300 may not include an audio input device 1318 (e.g., microphone) or an audio output device 1308 (e.g., a speaker, a headset, earbuds, etc.), but may include audio input or output device interface circuitry (e.g., connectors and supporting circuitry) to which an audio input device 1318 or audio output device 1308 may be coupled.

The electrical device 1300 may include programmable circuitry 1302 (e.g., one or more processing devices). The programmable circuitry 1302 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1300 may include a memory 1304, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1304 may include memory that shares a die with the programmable circuitry 1302. This memory may be used as cache memory and may include embedded dynamic random access memory (eDRAM) or spin transfer torque magnetic random access memory (STT-MRAM).

In some examples, the electrical device 1300 may include a communication chip 1312 (e.g., one or more communication chips). For example, the communication chip 1312 may be configured for managing wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1312 may operate in accordance with other wireless protocols in other examples. The electrical device 1300 may include an antenna to facilitate wireless communications and/or to receive other wireless communications (such as AM or FM radio transmissions).

In some examples, the communication chip 1312 may manage wired communications, such as electrical, optical, or any other suitable communication protocols (e.g., the Ethernet). As noted above, the communication chip 1312 may include multiple communication chips. For instance, a first communication chip 1312 may be dedicated to shorter-range wireless communications such as Wi-Fi or Bluetooth, and a second communication chip 1312 may be dedicated to longer-range wireless communications such as global positioning system (GPS), EDGE, GPRS, CDMA, WiMAX, LTE, EV-DO, or others. In some examples, a first communication chip 1312 may be dedicated to wireless communications, and a second communication chip 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display 1306 (or corresponding interface circuitry, as discussed above). The display 1306 may include any visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any device that generates an audible indicator, such as speakers, headsets, or earbuds.

The electrical device 1300 may include an audio input device 1318 (or corresponding interface circuitry, as discussed above). The audio input device 1318 may include any device that generates a signal representative of a sound, such as microphones, microphone arrays, or digital instruments (e.g., instruments having a musical instrument digital interface (MIDI) output).

The electrical device 1300 may include GPS circuitry 1316. The GPS circuitry 1316 may be in communication with a satellite-based system and may receive a location of the electrical device 1300, as known in the art.

The electrical device 1300 may include any other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include any other input device 1320 (or corresponding interface circuitry, as discussed above). Examples of the other input device 1320 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1300 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that increase the surface area of an example glass panel to provide greater adhesion between the glass panel and a frame. For example, disclosed examples taper and/or otherwise alter the shape of the glass panel to provide a relatively larger surface area to which a frame can bond. Additionally or alternatively, disclosed examples provide trenches, grooves, cavities, etc., in an example glass panel to increase the surface area of the glass panel. Accordingly, an example frame can seep, percolate, and/or extend into such trenches to bond with the glass panel. To that end, disclosed examples provide greater opportunity (by increased surface area) for the frame to effectively bond, grip to, and/or reconstitute with an example glass panel. Thus, disclosed examples can reduce and/or eliminate the delamination between a frame and a glass panel to an associated IC package.

Example 1 includes a hybrid core of an integrated circuit (IC) package comprising a frame, and a glass panel including a top surface, an edge adjacent the frame, and a tapered surface extending between the edge and the top surface.

Example 2 includes the hybrid core of the IC package of example 1, wherein the edge is a first edge, the tapered surface is a first tapered surface, further including a second edge adjacent to the frame, and a second tapered surface extending between the second edge and the top surface.

Example 3 includes the hybrid core of the IC package of any of example 1 or example 2, wherein the tapered surface includes a trench, and the frame includes an anchor extending at least partially in the trench.

Example 4 includes the hybrid core of the IC package of any of examples 1-3, wherein the frame is in contact with the top surface and the edge.

Example 5 includes the hybrid core of the IC package of any of examples 1-4, wherein the tapered surface is a first tapered surface, and the glass panel further includes a bottom surface, and a second tapered surface extending between the edge and the bottom surface.

Example 6 includes the hybrid core of the IC package of any of examples 1-5, wherein the first tapered surface and the second tapered surface are a same length.

Example 7 includes the hybrid core of the IC package of any of examples 1-6, wherein the glass panel includes a first portion including the top surface, the first tapered surface, and a first mounting surface opposite the top surface, and a second portion including the bottom surface, the second tapered surface, and a second mounting surface opposite the bottom surface, the second mounting surface coupled to the first mounting surface.

Example 8 includes a hybrid core of an integrated circuit (IC) package comprising a frame including an anchor, and a glass panel including a surface abutting the frame, and a cavity extending from the surface into the glass panel, the cavity receiving the anchor.

Example 9 includes the hybrid core of the IC package of example 8, wherein the surface is a tapered surface extending between a top surface of the glass panel and an edge surface of the glass panel.

Example 10 includes the hybrid core of the IC package of any of example 8 or example 9, wherein the surface is a top surface of the glass panel.

Example 11 includes the hybrid core of the IC package of any of examples 8-10, wherein the glass panel further includes a bottom surface, and an edge surface extending between the bottom surface and the top surface, the cavity adjacent to the edge surface.

Example 12 includes the hybrid core of the IC package of any of examples 8-11, wherein the cavity is a first cavity, and the glass panel further includes a second cavity extending from the edge surface into the glass panel.

Example 13 includes the hybrid core of the IC package of any of examples 8-12, wherein the frame includes a plurality of anchors including the anchor, and the glass panel includes a plurality of cavities including the cavity, each of the plurality of cavities receiving a corresponding anchor of the plurality of anchors.

Example 14 includes the hybrid core of the IC package of any of examples 8-13, further including a via extending through the glass panel, the plurality of cavities disposed between the via and an edge of the glass panel.

Example 15 includes the hybrid core of the IC package of any of examples 8-14, wherein the cavity has a depth of less than 5 micrometers.

Example 16 includes an integrated circuit (IC) package comprising a package substrate including a hybrid core including a dielectric layer including a cavity extending therethrough, and a glass panel within the cavity, the glass panel including at least one trench receiving at least a portion of the dielectric layer, and a die mounted on the package substrate.

Example 17 includes the IC package of example 16, wherein the glass panel includes a first tapered surface, and wherein the cavity includes a second tapered surface aligned with the first tapered surface.

Example 18 includes the IC package of any of example 16 or example 17, wherein the first tapered surface includes the at least one trench.

Example 19 includes the IC package of any of examples 16-18, wherein the at least one trench is included in a pattern of trenches, the pattern of trenches distributed along a side of the glass panel.

Example 20 includes the IC package of any of examples 16-19, wherein the side is a first side and the pattern is a first pattern, further including a second pattern of trenches distributed along a second side of the glass panel, the second side opposing the first side.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A hybrid core of an integrated circuit (IC) package comprising:
a frame; and
a glass panel including:
a top surface;
an edge adjacent the frame; and
a tapered surface extending between the edge and the top surface.

2. The hybrid core of the IC package of claim 1, wherein the edge is a first edge, the tapered surface is a first tapered surface, further including:
a second edge adjacent to the frame; and
a second tapered surface extending between the second edge and the top surface.

3. The hybrid core of the IC package of claim 1, wherein:
the tapered surface includes a trench; and
the frame includes an anchor extending at least partially in the trench.

4. The hybrid core of the IC package of claim 1, wherein the frame is in contact with the top surface and the edge.

5. The hybrid core of the IC package of claim 1, wherein the tapered surface is a first tapered surface, and the glass panel further includes:
a bottom surface; and
a second tapered surface extending between the edge and the bottom surface.

6. The hybrid core of the IC package of claim 5, wherein the first tapered surface and the second tapered surface are a same length.

7. The hybrid core of the IC package of claim 5, wherein the glass panel includes:
a first portion including the top surface, the first tapered surface, and a first mounting surface opposite the top surface; and
a second portion including the bottom surface, the second tapered surface, and a second mounting surface opposite the bottom surface, the second mounting surface coupled to the first mounting surface.

8. A hybrid core of an integrated circuit (IC) package comprising:
a frame including an anchor; and
a glass panel including:
a surface abutting the frame; and
a cavity extending from the surface into the glass panel, the cavity receiving the anchor.

9. The hybrid core of the IC package of claim 8, wherein the surface is a tapered surface extending between a top surface of the glass panel and an edge surface of the glass panel.

10. The hybrid core of the IC package of claim 8, wherein the surface is a top surface of the glass panel.

11. The hybrid core of the IC package of claim 10, wherein the glass panel further includes:
a bottom surface; and
an edge surface extending between the bottom surface and the top surface, the cavity adjacent to the edge surface.

12. The hybrid core of the IC package of claim 11, wherein the cavity is a first cavity, and the glass panel further includes a second cavity extending from the edge surface into the glass panel.

13. The hybrid core of the IC package of claim 8, wherein:
the frame includes a plurality of anchors including the anchor; and
the glass panel includes a plurality of cavities including the cavity, each of the plurality of cavities receiving a corresponding anchor of the plurality of anchor.

14. The hybrid core of the IC package of claim 13, further including a via extending through the glass panel, the plurality of cavities disposed between the via and an edge of the glass panel.

15. The hybrid core of the IC package of claim 13, wherein the cavity has a depth of less than 5 micrometers.

16. An integrated circuit (IC) package comprising:
a package substrate including a hybrid core, the hybrid core including:
a dielectric layer including a cavity extending therethrough; and
a glass panel within the cavity, the glass panel including at least one trench receiving at least a portion of the dielectric layer; and
a die mounted on the package substrate.

17. The IC package of claim 16, wherein the glass panel includes a first tapered surface, and wherein the cavity includes a second tapered surface aligned with the first tapered surface.

18. The IC package of claim 17, wherein the first tapered surface includes the at least one trench.

19. The IC package of claim 16, wherein the at least one trench is included in a pattern of trenches, the pattern of trenches distributed along a side of the glass panel.

20. The IC package of claim 19, wherein the side is a first side and the pattern is a first pattern, further including a second pattern of trenches distributed along a second side of the glass panel, the second side opposing the first side.
